(19) United States
(12) Patent Application Publication
(10) Pub. No.: US 2026/0182433 A1
(43) Pub. Date: Jun. 25, 2026

(54) SEMICONDUCTOR DEVICE

(71) Applicant: Samsung Electronics Co., Ltd., Suwon-si (KR)

(72) Inventors: JOO HEE JANG, Suwon-si (KR); HO-JIN LEE, Suwon-si (KR); SEOKHO KIM, Suwon-si (KR); KYU-HA LEE, Suwon-si (KR); DONG-CHAN LIM, Suwon-si (KR)

(21) Appl. No.: 19/246,772

(22) Filed: Jun. 24, 2025

(30) Foreign Application Priority Data
Dec. 20, 2024 (KR) 10-2024-0193104

(51) Int. Cl. H01L 23/00

(52) U.S. Cl. CPC H10W 72/90; H10W 99/00; H10W 72/951; H10W 90/792

(57) ABSTRACT

Disclosed is a semiconductor device comprising a first semiconductor die and a second semiconductor die on the first semiconductor die. The first semiconductor die comprises a first pad, a first dielectric pattern that surrounds a lateral surface of the first pad, and a second dielectric pattern that surrounds a lateral surface of the first dielectric pattern. The second semiconductor die comprises a second pad in contact with the first pad. The first dielectric pattern comprises a first dielectric material. The second dielectric pattern comprises a second dielectric material different from the first dielectric material. A thermal conductivity of the second dielectric material is greater than a thermal conductivity of the first dielectric material.

### CROSS-REFERENCE TO RELATED APPLICATION

This application claims priority under 35 U.S.C. § 119 to Korean Patent Application No. 10-2024-0193104 filed on Dec. 20, 2024, in the Korean Intellectual Property Office, the disclosure of which is hereby incorporated by reference in its entirety.

### BACKGROUND

The present inventive concepts relate to a semiconductor device.

In general, a semiconductor device has a structure in which a semiconductor die is mounted on a printed circuit board and a bonding wire or a bump is used to electrically connect the semiconductor die and the printed circuit board. With the high integration of the semiconductor device, there is developed a technique in which a pad is used to electrically connect the semiconductor die, and various studies are being conducted to improve reliability of the semiconductor device.

### SUMMARY

Some embodiments of the present inventive concepts provide a semiconductor device with improved reliability.

According to some embodiments of the present inventive concepts, a semiconductor device may comprise: a first semiconductor die; and a second semiconductor die on the first semiconductor die. The first semiconductor die may comprise: a first pad; a first dielectric pattern that surrounds a lateral surface of the first pad; and a second dielectric pattern that surrounds a lateral surface of the first dielectric pattern. The second semiconductor die may comprise a second pad in contact with the first pad. The first dielectric pattern may comprise a first dielectric material. The second dielectric pattern may comprise a second dielectric material different from the first dielectric material. A thermal conductivity of the second dielectric material may be greater than a thermal conductivity of the first dielectric material.

According to some embodiments of the present inventive concepts, a semiconductor device may comprise: a first semiconductor die; and a second semiconductor die on the first semiconductor die. The first semiconductor die may comprise: a first pad; a first dielectric pattern that surrounds a lateral surface of the first pad; and a second dielectric pattern on a top surface of the first dielectric pattern and surrounding the lateral surface of the first pad. The second semiconductor die may comprise a second pad in contact with the first pad. The first dielectric pattern may comprise a first dielectric material. The second dielectric pattern may comprise a second dielectric material different from the first dielectric material. The first dielectric material may comprise at least one selected from silicon oxide, silicon nitride, silicon oxynitride, and any mixture thereof. A thermal conductivity of the second dielectric material may be greater than a thermal conductivity of the first dielectric material.

According to some embodiments of the present inventive concepts, a semiconductor device may comprise: a first semiconductor die; and a second semiconductor die on the first semiconductor die. The first semiconductor die may comprise: a wiring pattern; a dielectric layer that surrounds a lateral surface of the wiring pattern; a first pad on the wiring pattern; and a dielectric pattern that surrounds a lateral surface of the first pad. The second semiconductor die may comprise a second pad in contact with the first pad. The dielectric layer may comprise a first dielectric material. The dielectric pattern may comprise a second dielectric material different from the first dielectric material. The first dielectric material may comprise at least one selected from silicon oxide, silicon nitride, silicon oxynitride, and any mixture thereof. A thermal conductivity of the second dielectric material may be greater than a thermal conductivity of the first dielectric material.

### BRIEF DESCRIPTION OF DRAWINGS

FIG. 1 illustrates a plan view showing a semiconductor device according to some example embodiments of the present inventive concepts.

FIG. 2 illustrates a cross-sectional view taken along line A-A′ of FIG. 1.

FIG. 3 illustrates a plan view showing a semiconductor device according to some example embodiments of the present inventive concepts.

FIG. 4 illustrates a cross-sectional view taken along line B-B′ of FIG. 3.

FIG. 5 illustrates a plan view showing a semiconductor device according to some example embodiments of the present inventive concepts.

FIG. 6 illustrates a cross-sectional view taken along line C-C′ of FIG. 5.

FIGS. 7A and 7B illustrate enlarged views showing section R1 of FIG. 6.

FIG. 8 illustrates a plan view showing a semiconductor device according to some example embodiments of the present inventive concepts.

FIG. 9 illustrates a cross-sectional view taken along line C-C′ of FIG. 8.

FIGS. 10A, 10B, 10C, and 10D illustrate enlarged views showing section R2 of FIG. 9.

FIG. 11 illustrates a plan view showing a semiconductor device according to some example embodiments of the present inventive concepts.

FIG. 12 illustrates a cross-sectional view taken along line C-C′ of FIG. 11.

FIGS. 13A, 13B, and 13C illustrate enlarged views showing section R2 of FIG. 12.

FIGS. 14A, 14B, 14C, 14D, 14E, 14F, and 14G illustrate cross-sectional views showing a method of manufacturing a semiconductor device according to some example embodiments of the present inventive concepts.

FIGS. 15A and 15B illustrate cross-sectional views showing a method of manufacturing a semiconductor device according to some example embodiments of the present inventive concepts.

### DETAILED DESCRIPTION OF EMBODIMENTS

Some embodiments of the present inventive concepts will now be described in detail with reference to the accompanying drawings to aid in clearly explaining the present inventive concepts. Like reference characters refer to like elements throughout.

Terms such as “same,” “equal,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to emphasize this meaning, unless the context or other statements indicate otherwise.

Terms such as “about” or “approximately” may reflect amounts, sizes, orientations, or layouts that vary only in a small relative manner, and/or in a way that does not significantly alter the operation, functionality, or structure of certain elements. For example, a range from “about 0.1 to about 1” may encompass a range such as a 0%-5% deviation around 0.1 and a 0% to 5% deviation around 1, especially if such deviation maintains the same effect as the listed range.

Spatially relative terms, such as “beneath,” “below,” “lower,” “above,” “upper” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

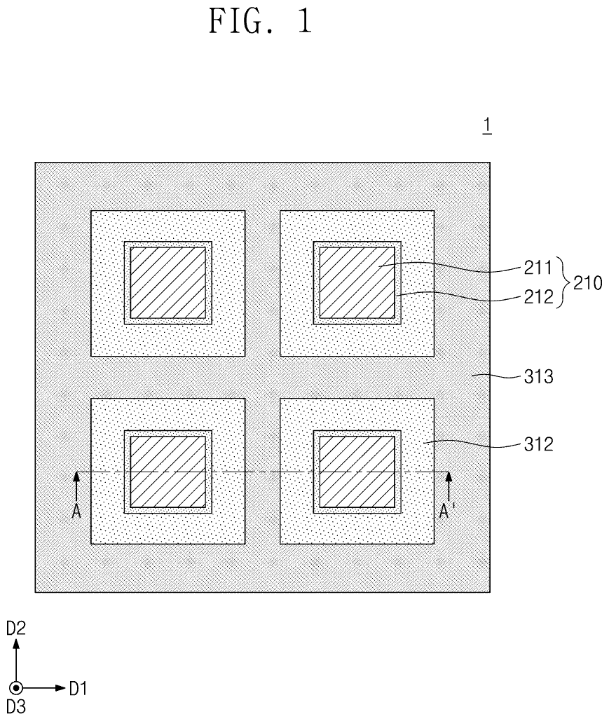

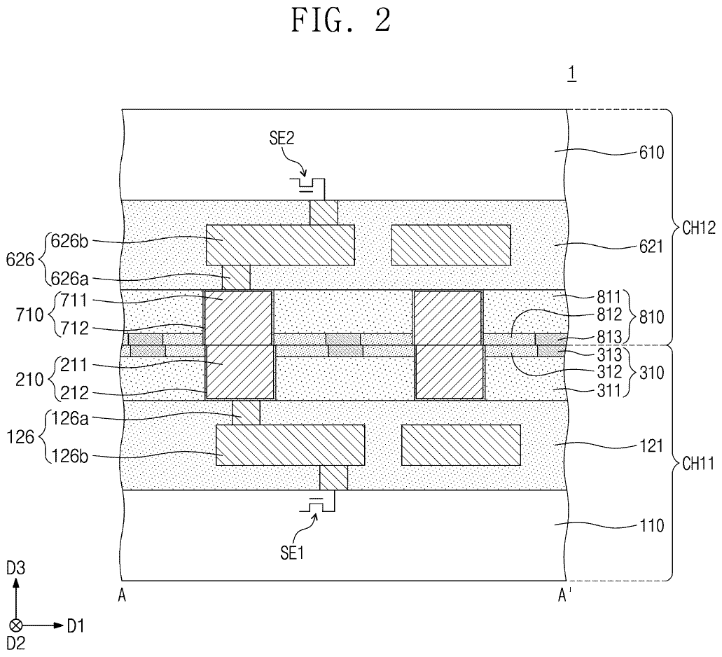

FIG. 1 illustrates a plan view showing a semiconductor device according to some example embodiments of the present inventive concepts. FIG. 2 illustrates a cross-sectional view taken along line A-A′ of FIG. 1.

Referring to FIGS. 1 and 2, a semiconductor device 1 according to the present inventive concepts may include a first semiconductor die CH11 and a second semiconductor die CH12 on the first semiconductor die CH11.

The first semiconductor die CH11 may include a first semiconductor substrate 110, a first wiring pattern 126, a first dielectric layer 121, a first pad 210, a first dielectric pattern 311, a second dielectric pattern 312, and a third dielectric pattern 313. The first dielectric pattern 311, the second dielectric pattern 312, and the third dielectric pattern 313 may constitute a first dielectric structure 310.

The first semiconductor substrate 110 may have a top surface that extends in a first direction D1 and a second direction D2 orthogonal to the first direction D1. The first semiconductor substrate 110 may include a semiconductor element, such as silicon (Si) or germanium (Ge). The first semiconductor substrate 110 may include a first circuit layer SE1. The first circuit layer SE1 may include at least one transistor. The first circuit layer SE1 may be a portion of a circuit that constitutes the semiconductor device 1, which semiconductor device 1 may be, but is not limited to, a complementary metal oxide semiconductor image sensor (CIS) device, a bonding vertical NAND (BVNAND) device, a dynamic random access memory (DRAM) device, a high bandwidth memory (HBM) device, a 3D-IC device, or a backside power delivery network (BSPDN) device. The first circuit layer SE1 may be disposed on the first wiring pattern 126 which will be discussed below, but the present inventive concepts are not limited thereto.

The first wiring pattern 126 may be provided on the top surface of the first semiconductor substrate 110. The first wiring pattern 126 may include a first via 126a and a first line 126b on the first via 126a. The first via 126a may extend in a third direction D3 perpendicular to the top surface of the first semiconductor substrate 110. The first line 126b may extend lengthwise in the first direction D1 and/or the second direction D2. Each of the first via 126a and the first line 126b may be provided in plural. The first wiring pattern 126 may be electrically connected to the first circuit layer SE1 of the first semiconductor substrate 110. Although not shown, the first wiring pattern 126 may include an additional via and/or line. For example, another first via 126a may be provided below the first line 126b. In addition, a further first line 126b may be provided below the another first via 126a. The first lines 126b may be disposed spaced apart in the third direction D3 from each other, and the first vias 126a may lie between and electrically connect the first lines 126b that are spaced apart in the third direction D3 from each other.

The first dielectric layer 121 may be provided on the top surface of the first semiconductor substrate 110. The first dielectric layer 121 may contact the top surface of the first semiconductor substrate 110. The first dielectric layer 121 may surround a lateral surface of the first wiring pattern 126. The first dielectric layer 121 may contact the lateral surface of the first wiring pattern 126. A top surface of an uppermost first via 126a may be coplanar with a top surface of the first dielectric layer 121. The first dielectric layer 121 may include a first dielectric material. The first dielectric material may have a thermal conductivity of equal to or less than about 10 W/m·K. For example, the first dielectric material may include at least one selected from silicon oxide, silicon nitride, silicon oxynitride, and any mixture thereof. In this description, silicon oxide may include silicon oxycarbide, and silicon nitride may include silicon carbonitride.

Referring to FIG. 2, the first dielectric layer 121 is illustrated as a single dielectric layer, but the present inventive concepts are not limited thereto. Alternatively, the first dielectric layer 121 may include two or more dielectric layers. In this case, each of the dielectric layers included in the first dielectric layer 121 may include the first dielectric material.

Referring back to FIGS. 1 and 2, the first pad 210 may be provided on the first wiring pattern 126. The first pad 210 may be provided in plural. The first pads 210 may be provided on the first vias 126a. Bottom surfaces of the first pads 210 may contact top surfaces of uppermost ones of the first vias 126a.

The first pad 210 may include a first barrier pattern 212 on the first wiring pattern 126 and a first conductive pattern 211 on the first barrier pattern 212. The first barrier pattern 212 may be provided on the first dielectric layer 121, the first dielectric pattern 311, and/or the second dielectric pattern 312. The first barrier pattern 212 may contact a top surface of the first dielectric layer 121, lateral surfaces of the first dielectric pattern 311, and/or lateral surfaces of the second dielectric pattern 312. A lateral surface and a bottom surface of the first conductive pattern 211 may be in direct contact with the first barrier pattern 212. Top surfaces of the first conductive pattern 211 and the first barrier pattern 212 may be coplanar. The first barrier pattern 212 may include a barrier material, such as at least one selected from nickel, titanium, and any mixture thereof. The first conductive pattern 211 may include a conductive material, such as copper.

The first dielectric pattern 311 may be provided on a top surface of the first dielectric layer 121. The first dielectric pattern 311 may contact the top surface of the first dielectric layer 121. The first dielectric pattern 311 may surround a lateral surface of the first pad 210, for example, a lateral surface of a lower portion of the first pad 210.

The first dielectric pattern 311 may include a second dielectric material. The second dielectric material may have a thermal conductivity of equal to or less than about 10 W/m·K. For example, the second dielectric material may include at least one selected from silicon oxide, silicon nitride, silicon oxynitride, and any mixture thereof.

The second dielectric material may be the same as or different from the first dielectric material. When the second dielectric material includes the same material as that of the first dielectric material, no interface may appear between the first dielectric layer 121 and the first dielectric pattern 311 depicted in FIG. 2. Referring to FIG. 2, the first dielectric pattern 311 is illustrated provided in the form of a single component, but the present inventive concepts are not limited thereto. For example, the first dielectric pattern 311 may include a plurality of dielectric layers that are stacked in the third direction D3. In this case, each of the dielectric layers included in the first dielectric pattern 311 may include a second dielectric material.

Referring still to FIGS. 1 and 2, the second dielectric pattern 312 may be provided on a top surface of the first dielectric pattern 311. The second dielectric pattern 312 may contact the top surface of the first dielectric pattern 311. The second dielectric pattern 312 may surround the lateral surface of the first pad 210, for example, the lateral surface of an upper portion of the first pad 210.

Referring to FIG. 1, the second dielectric pattern 312 may be provided in plural. Each of the second dielectric patterns 312 may surround the lateral surface of a corresponding first pad 210. Widths in the first direction D1 and the second direction D2 of each of the second dielectric patterns 312 may be less than those in the first direction D1 and the second direction D2 of the first dielectric pattern 311.

The second dielectric pattern 312 may include a third dielectric material. The third dielectric material may have a thermal conductivity of equal to or less than about 10 W/m·K. For example, the third dielectric material may include at least one selected from silicon oxide, silicon nitride, silicon oxynitride, and any mixture thereof.

The third dielectric material may be the same as or different from the first dielectric material. For example, no interface may appear between the first dielectric pattern 311 and the second dielectric pattern 312 depicted in FIG. 2. Referring to FIG. 2, the second dielectric pattern 312 is illustrated provided in the form of a single component, but the present inventive concepts are not limited thereto. For example, the second dielectric pattern 312 may include a plurality of dielectric layers that are stacked in the third direction D3. In this case, each of the dielectric layers included in the second dielectric pattern 312 may include the third dielectric material.

Referring again to FIGS. 1 and 2, the third dielectric pattern 313 may be provided on the top surface of the first dielectric pattern 311. The third dielectric pattern 313 may contact the top surface of the first dielectric pattern 311. The third dielectric pattern 313 may surround the lateral surface of the first pad 210, for example, the lateral surface of an upper portion of the first pad 210. The third dielectric pattern 313 may be adjacent in the first direction D1 and/or the second direction D2 to the second dielectric pattern 312. The third dielectric pattern 313 may surround a lateral surface of the second dielectric pattern 312. Top surfaces of the second dielectric pattern 312, the third dielectric pattern 313, and the first pads 210 may be coplanar.

The third dielectric pattern 313 may include a fourth dielectric material. The fourth dielectric material may have a thermal conductivity of greater than about 10 W/m·K or a thermal conductivity of about 30 W/m. K to about 3,000 W/m·K. For example, the fourth dielectric material may include at least one selected from aluminum oxide (AlO), aluminum nitride (AlN), boron nitride (BN), diamond, and any mixture thereof.

The second semiconductor die CH12 may include a second semiconductor substrate 610, a second wiring pattern 626, a second dielectric layer 621, a second pad 710, and a second dielectric structure 810.

The second semiconductor die CH12 and the first semiconductor die CH11 may be of the same or different types.

When the second semiconductor die CH12 and the first semiconductor die CH11 are of the same type, the second semiconductor die CH12 may include components substantially the same as those of the first semiconductor die CH11, only except that the second semiconductor die CH12 and the first semiconductor die CH11 are reversed in position.

When the second semiconductor die CH12 and the first semiconductor die CH11 are of different types, the second semiconductor die CH12 may include components that correspond to those of the first semiconductor die CH11, and the components of the second semiconductor die CH12 may be symmetric at 180° with respect to the components of the first semiconductor die CH11.

The second semiconductor substrate 610 may correspond to the first semiconductor substrate 110 of the first semiconductor die CH11. The second semiconductor substrate 610 may include a second circuit layer SE2. The second circuit layer SE2 may include at least one transistor. The second circuit layer SE2 may be a portion of a circuit that constitutes the semiconductor device 1, which semiconductor device 1 may be, but not limited to, a complementary metal oxide semiconductor image sensor (CIS) device, a bonding vertical NAND (BVNAND) device, a dynamic random access memory (DRAM) device, a high bandwidth memory (HBM) device, a 3D-IC device, or a backside power delivery network (BSPDN) device. The second circuit layer SE2 may have an integrated circuit the same as or different from that of the first circuit layer SE1. The second circuit layer SE2 may be disposed on the second wiring pattern 626 which will be discussed below, but the present inventive concepts are not limited thereto.

The second wiring pattern 626 may be provided on a bottom surface of the second semiconductor substrate 610. The second wiring pattern 626 may include a second via 626a and a second line 626b on the second via 626a. The second wiring pattern 626, the second via 626a, and the second line 626b may respectively correspond to the first wiring pattern 126, the first via 126a, and the first line 126b of the first semiconductor die CH11.

The second dielectric layer 621 may be provided on the bottom surface of the second semiconductor substrate 610. The second dielectric layer 621 may contact the bottom surface of the second semiconductor substrate 610. The second dielectric layer 621 may correspond to the first dielectric layer 121 of the first semiconductor die CH11.

The second pad 710 may be provided on the second wiring pattern 626. The second pad 710 may include a second barrier pattern 712 and a second conductive pattern 711 on the second barrier pattern 712. The second barrier pattern 712 may be provided on the second dielectric layer 621, the fourth dielectric pattern 811, and/or the fifth dielectric pattern 812. The second barrier pattern 712 may contact a bottom surface of the second dielectric layer 621, lateral surfaces of the fourth dielectric pattern 811, and/or lateral surfaces of the fifth dielectric pattern 812. A lateral surface and a top surface of the second conductive pattern 711 may be in direct contact with the second barrier pattern 712. Bottom surfaces of the second conductive pattern 711, the second barrier pattern 712, and the fifth dielectric pattern 812 may be coplanar. The second pad 710, the second barrier pattern 712, and the second conductive pattern 711 may respectively correspond to the first pad 210, the first barrier pattern 212, and the first conductive pattern 211 of the first semiconductor die CH11.

The second dielectric structure 810 may be provided on the second dielectric layer 621. The second dielectric structure 810 may contact a bottom surface of the second dielectric layer 621. The second dielectric structure 810 may include a fourth dielectric pattern 811, a fifth dielectric pattern 812 on the fourth dielectric pattern 811, and a sixth dielectric pattern 813 on the fourth dielectric pattern 811. The fifth dielectric pattern 812 and the sixth dielectric pattern 813 may contact a bottom surface of the fourth dielectric pattern 811. Bottom surfaces of the fifth dielectric pattern 812 and the sixth dielectric pattern 813 may be coplanar. The second dielectric structure 810, the fourth dielectric pattern 811, the fifth dielectric pattern 812, and the sixth dielectric pattern 813 may respectively correspond to the first dielectric structure 310, the first dielectric pattern 311, the second dielectric pattern 312, and the third dielectric pattern 313 of the first semiconductor die CH11.

Referring to FIG. 2, the semiconductor device 1 may have a hybrid bonding structure. A top surface of the first semiconductor die CH11 may be bonded to a bottom surface of the second semiconductor die CH12. For example, a top surface of the first pad 210 may be bonded to a bottom surface of the second pad 710, a top surface of the second dielectric pattern 312 may be bonded to a bottom surface of the fifth dielectric pattern 812, and a top surface of the third dielectric pattern 313 may be bonded to a bottom surface of the sixth dielectric pattern 813.

The semiconductor device 1 according to some embodiments of the present inventive concepts may include the first dielectric pattern 311 whose planarization efficiency is high to facilitate bonding between semiconductor dies when hybrid bonding is executed, the second dielectric pattern 312 whose bonding strength is high, and the third dielectric pattern 313 whose thermal conductivity is high, and may show an arrangement of the dielectric patterns 311, 312, and 313. Thus, it may be possible to increase strength of the hybrid bonding and to easily disperse and discharge heat generated from pads and lines included in the semiconductor device 1. As a result, the semiconductor device 1 may improve in reliability.

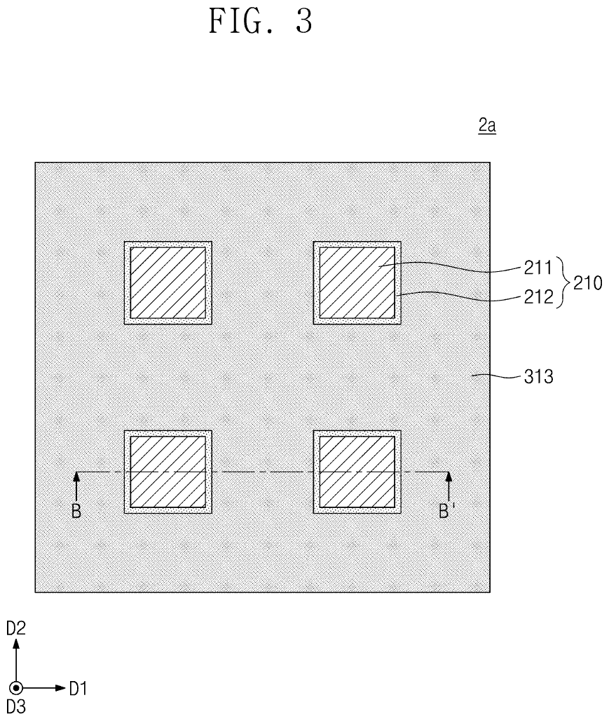

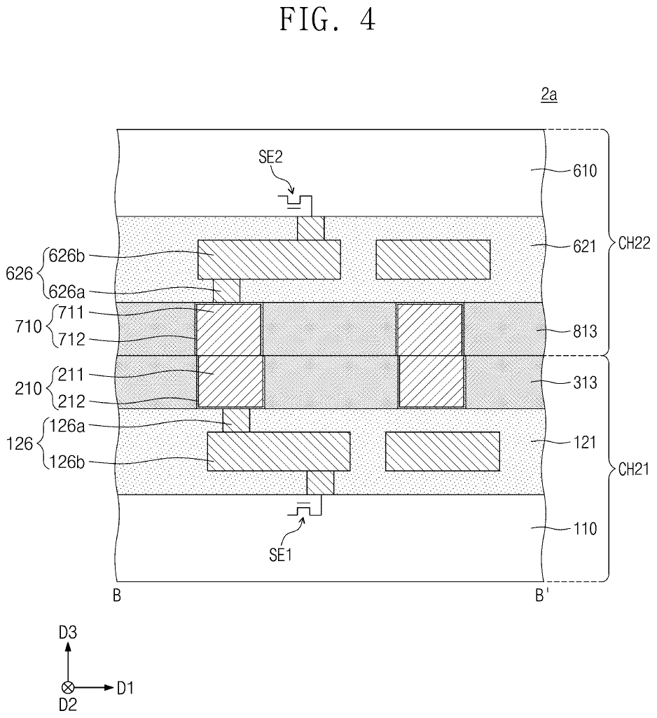

FIG. 3 illustrates a plan view showing a semiconductor device according to some example embodiments of the present inventive concepts. FIG. 4 illustrates a cross-sectional view taken along line B-B′ of FIG. 3. For brevity of description below, omission will be made to avoid an explanation repetitive to that of FIGS. 1 and 2.

Referring to FIGS. 3 and 4, a semiconductor device 2a according to some embodiments of the present inventive concepts may include a third semiconductor die CH21 and a fourth semiconductor die CH22 on the third semiconductor die cH21.

Referring to FIGS. 3 and 4 together with FIGS. 1 and 2, unlike the first semiconductor die CH11 of the semiconductor device 1, the third semiconductor die CH21 may include none of the first dielectric pattern 311 and the second dielectric pattern 312. Unlike the second semiconductor die CH12 of the semiconductor device 1, the fourth semiconductor die CH22 may include none of the fourth dielectric pattern 811 and the fifth dielectric pattern 812.

Referring back to FIGS. 3 and 4, the third dielectric pattern 313 may be provided on a top surface of the first dielectric layer 121. The third dielectric pattern 313 may surround a lateral surface of the first pad 210, for example, lateral surfaces of upper and lower portions of the first pad 210.

The sixth dielectric pattern 813 of the fourth semiconductor die CH22 may have a configuration substantially the same as that of the third dielectric pattern 313 of the third semiconductor die CH21.

Referring to FIG. 4, the semiconductor device 2a may have a hybrid bonding structure. A top surface of the third semiconductor die CH21 may be bonded to a bottom surface of the fourth semiconductor die CH22. For example, a top surface of the first pad 210 may be bonded to a bottom surface of the second pad 710, and a top surface of the third dielectric pattern 313 may be bonded to a bottom surface of the sixth dielectric pattern 813.

The semiconductor device 2a according to some embodiments of the present inventive concepts may include the third dielectric pattern 313 whose thermal conductivity is high. Thus, it may be possible to easily disperse and discharge heat generated from pads and lines included in the semiconductor device 2a. As a result, the semiconductor device 2a may improve in reliability.

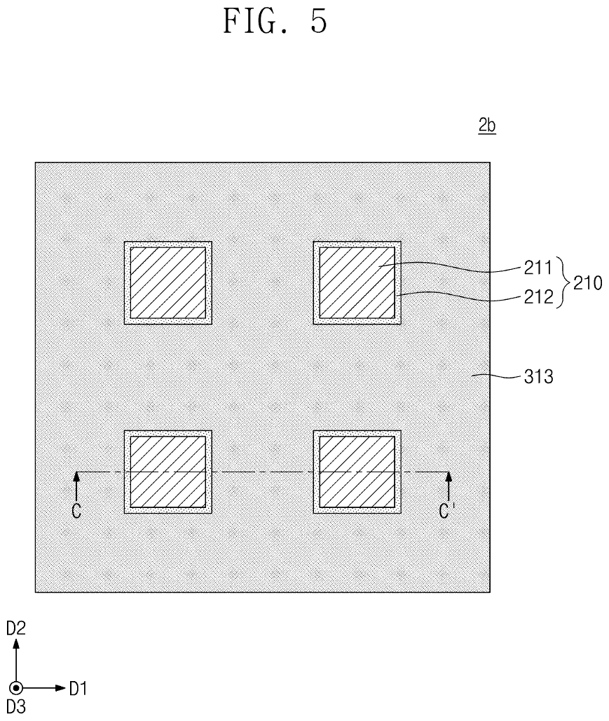

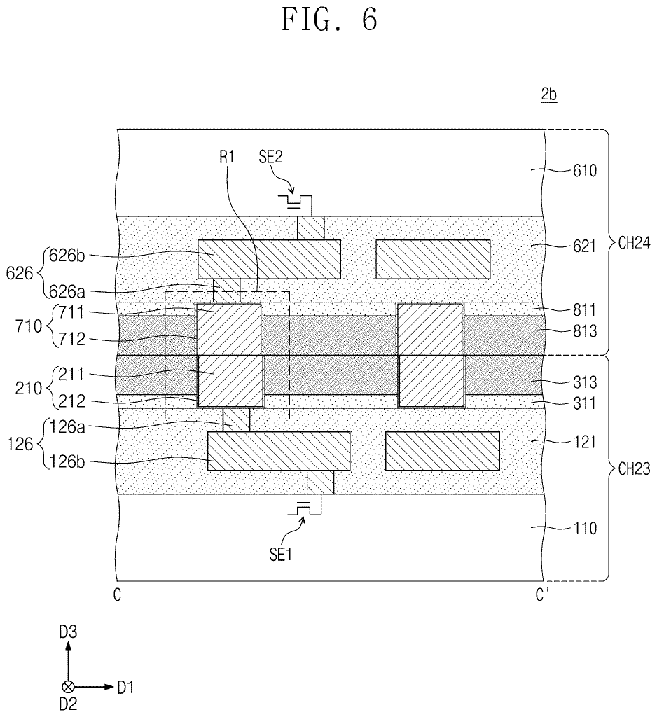

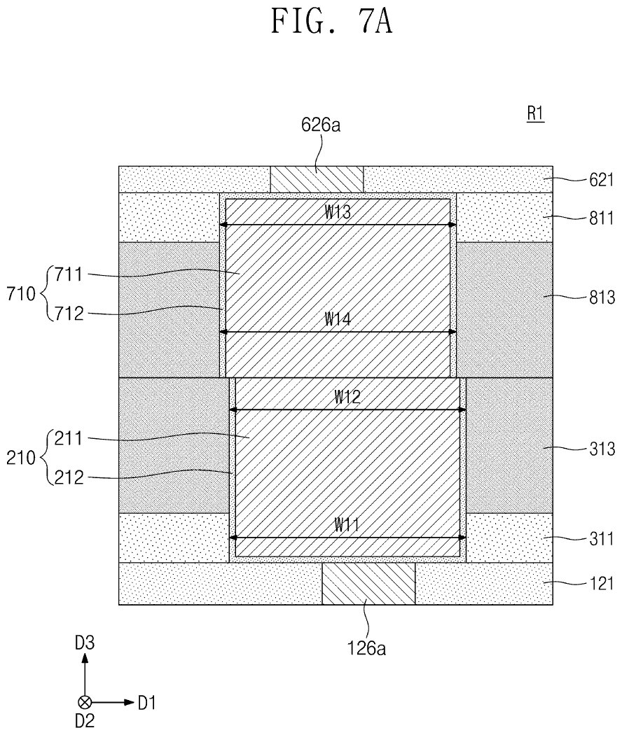

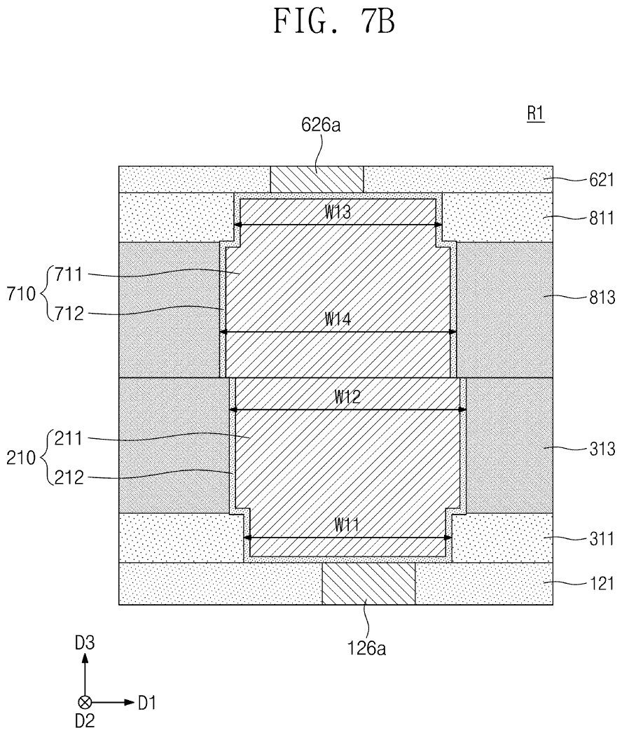

FIG. 5 illustrates a plan view showing a semiconductor device according to some example embodiments of the present inventive concepts. FIG. 6 illustrates a cross-sectional view taken along line C-C′ of FIG. 5. FIGS. 7A and 7B illustrate enlarged views showing section R1 of FIG. 6. For brevity of description below, omission will be made to avoid an explanation repetitive to that of FIGS. 1 and 2.

Referring to FIGS. 5 and 6, a semiconductor device 2b according to some embodiments of the present inventive concepts may include a fifth semiconductor die CH23 and a sixth semiconductor die CH24 on the fifth semiconductor die CH23.

Referring to FIGS. 5 and 6 together with FIGS. 1 and 2, unlike the first semiconductor die CH11 of the semiconductor device 1, the fifth semiconductor die CH23 may not include the second dielectric pattern 312. Unlike the second semiconductor die CH12 of the semiconductor device 1, the sixth semiconductor die CH24 may not include the fifth dielectric pattern 315.

Referring back to FIGS. 5 and 6, the third dielectric pattern 313 may be provided on a top surface of the first dielectric pattern 311. The third dielectric pattern 313 may surround a lateral surface of the first pad 210, for example, a lateral surface of an upper portion of the first pad 210. For example, the third dielectric pattern 313 may contact the top surface of the first dielectric pattern 311 and lateral surfaces of the first pads 210. The top surface of the third dielectric pattern 313 may be coplanar with top surfaces of the first pads 210.

Referring to FIG. 6, the semiconductor device 2b may have a hybrid bonding structure. A top surface of the fifth semiconductor die CH23 may be bonded to a bottom surface of the sixth semiconductor die CH24. For example, a top surface of the first pad 210 may be bonded to a bottom surface of the second pad 710, and a top surface of the third dielectric pattern 313 may be bonded to a bottom surface of the sixth dielectric pattern 813.

Referring to FIG. 7A, a width W12 in a horizontal direction (e.g., the first direction D1) of a portion of the first pad 210 surrounded by the third dielectric pattern 313 may be substantially the same as a width W11 in the horizontal direction (e.g., the first direction D1) of a portion of the first pad 210 surrounded by the first dielectric pattern 311. Likewise, a width W13 of a portion of the second pad 710 surrounded by the sixth dielectric pattern 813 may be substantially the same as a width W13 of a portion of the second pad 710 surrounded by the fourth dielectric pattern 811.

Referring to FIG. 7B, a width W12 in the horizontal direction (e.g., the first direction D1) of a portion of the first pad 210 surrounded by the third dielectric pattern 313 may be greater than a width W11 in the horizontal direction (e.g., the first direction D1) of a portion of the first pad 210 surrounded by the first dielectric pattern 311. Likewise, a width W14 in the horizontal direction (e.g., the first direction D1) of a portion of the second pad 710 surrounded by the sixth dielectric pattern 813 may be greater than a width W13 in the horizontal direction (e.g., the first direction D1) of a portion of the second pad 710 surrounded by the fourth dielectric pattern 811.

The semiconductor device 2b according to some embodiments of the present inventive concepts may include the first dielectric pattern 311 whose planarization efficiency is high to facilitate bonding between semiconductor dies when hybrid bonding is executed and the third dielectric pattern 313 whose thermal conductivity is high, and may show an arrangement of the dielectric patterns 311 and 313. Thus, it may be possible to increase strength of the hybrid bonding and to easily disperse and discharge heat generated from pads and lines included in the semiconductor device 2b. As a result, the semiconductor device 2b may improve in reliability.

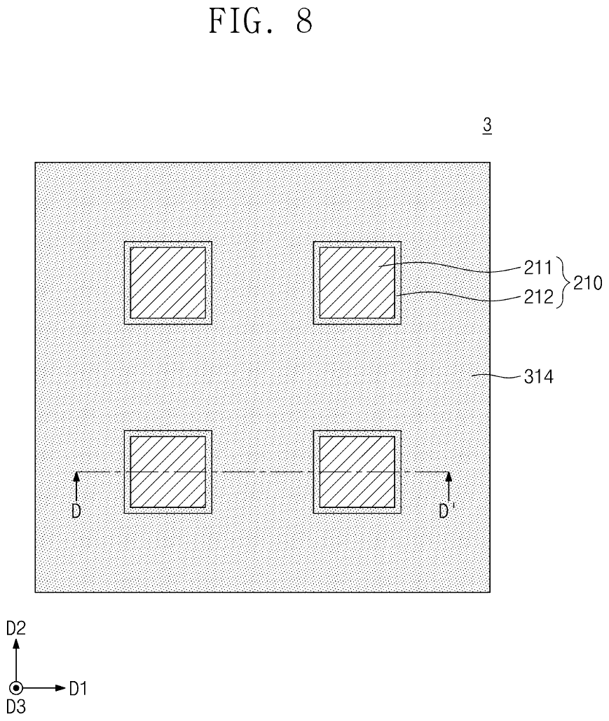

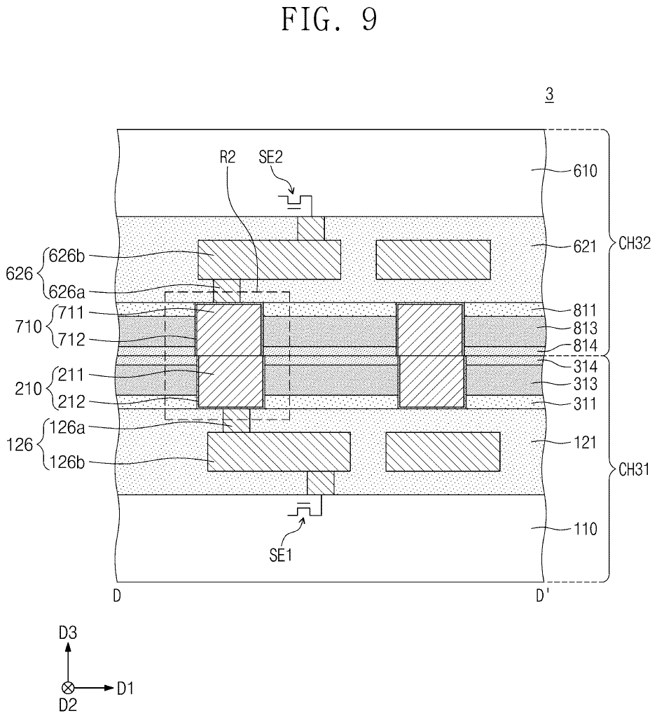

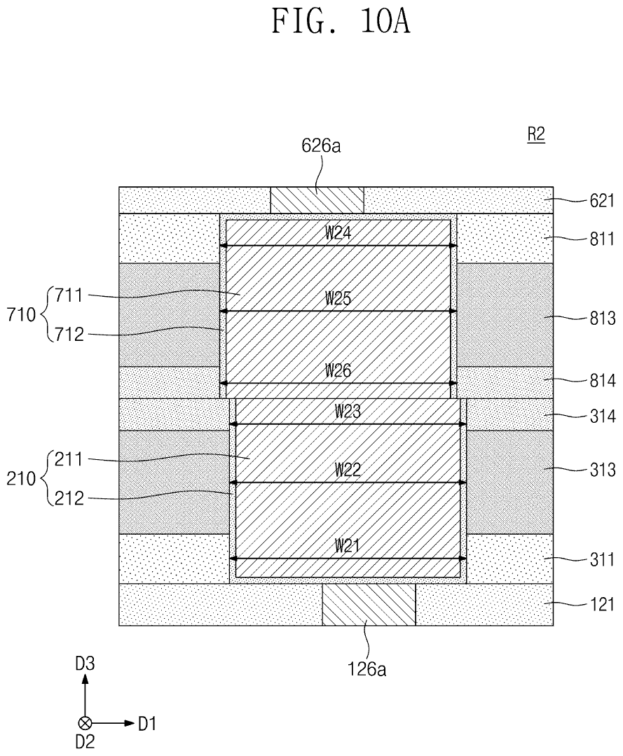

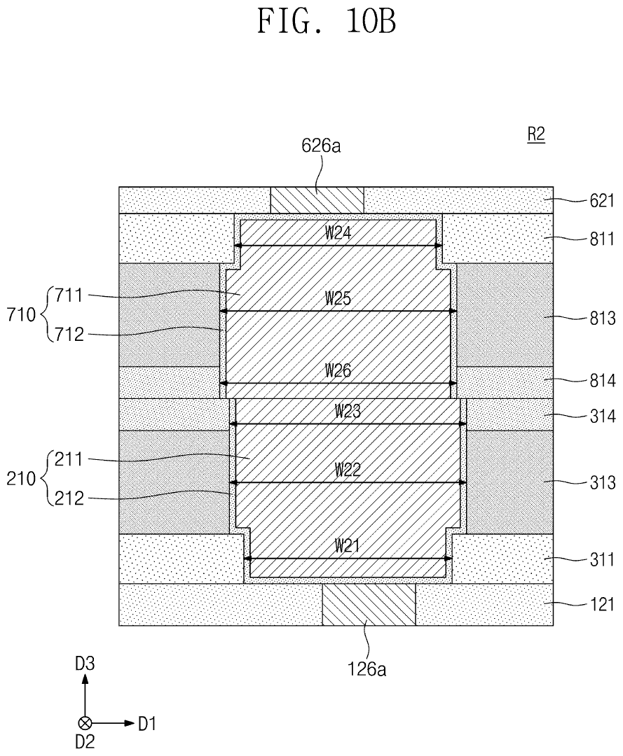

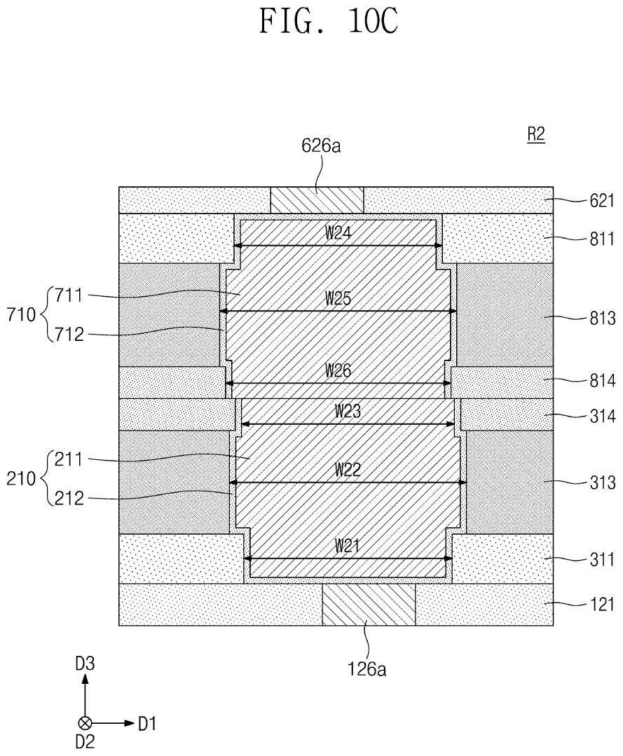

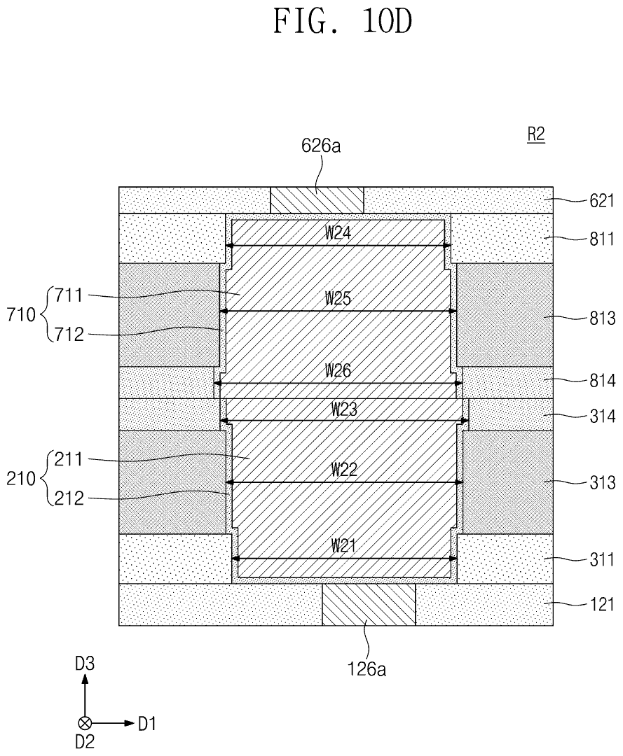

FIG. 8 illustrates a plan view showing a semiconductor device according to some example embodiments of the present inventive concepts. FIG. 9 illustrates a cross-sectional view taken along line C-C′ of FIG. 8. FIGS. 10A, 10B, 10C, and 10D illustrate enlarged views showing section R2 of FIG. 9. For brevity of description below, omission will be made to avoid an explanation repetitive to that of FIGS. 1 and 2.

Referring to FIGS. 8 and 9, a semiconductor device 3 according to some embodiments of the present inventive concepts may include a seventh semiconductor die CH31 and an eighth semiconductor die CH32 on the seventh semiconductor die CH31.

Referring to FIGS. 8 and 9 together with FIGS. 1 and 2, unlike the first semiconductor die CH11 of the semiconductor device 1, the seventh semiconductor die CH31 may not include the second dielectric pattern 312 and may further include a seventh dielectric pattern 314. Unlike the second semiconductor die CH12 of the semiconductor device 1, the eighth semiconductor die CH32 may not include the fifth dielectric pattern 812 and may further include an eighth dielectric pattern 814.

Referring back to FIGS. 8 and 9, the third dielectric pattern 313 may be provided on a top surface of the first dielectric pattern 311. The third dielectric pattern 313 may surround a lateral surface of the first pad 210, for example, a lateral surface of an intermediate portion of the first pad 210. For example, the third dielectric pattern 313 may contact the top surface of the first dielectric pattern 311 and the lateral surface of an intermediate portion of the first pad 210.

The seventh dielectric pattern 314 may be provided on a top surface of the third dielectric pattern 313. The seventh dielectric pattern 314 may surround a lateral surface of the first pad 210, for example, a lateral surface of an upper portion of the first pad 210. For example, the seventh dielectric pattern 314 may contact the top surface of the third dielectric pattern 313 and the lateral surface of an upper portion of the first pad 210.

The sixth dielectric pattern 813 may be provided on a bottom surface of the fourth dielectric pattern 811. The sixth dielectric pattern 813 may surround a lateral surface of the first pad 210, for example, a lateral surface of an intermediate portion of the first pad 210. For example, the sixth dielectric pattern 813 may contact the top surface of the fourth dielectric pattern 811 and the lateral surface of an intermediate portion of the first pad 210.

The eighth dielectric pattern 814 may be provided on a top surface of the sixth dielectric pattern 813. The eighth dielectric pattern 814 may surround a lateral surface of the first pad 210, for example, a lateral surface of an upper portion of the first pad 210. For example, the eighth dielectric pattern 814 may contact the top surface of the sixth dielectric pattern 813 and the lateral surface of an upper portion of the first pad 210.

The seventh dielectric pattern 314 and the eighth dielectric pattern 814 each may include a fifth dielectric material. The fifth dielectric material may have a thermal conductivity of greater than about 10 W/m·K or a thermal conductivity of about 30 W/m·K to about 3,000 W/m·K. For example, the fifth dielectric material may include at least one selected from aluminum oxide (AIO), aluminum nitride (AlN), boron nitride (BN), diamond, and any mixture thereof.

The eighth dielectric pattern 814 of the eighth semiconductor die CH32 may correspond to the seventh dielectric pattern 314 of the seventh semiconductor die CH31.

Referring to FIG. 9, the semiconductor device 3 may have a hybrid bonding structure. A top surface of the seventh semiconductor die CH31 may be bonded to a bottom surface of the eighth semiconductor die CH32. For example, a top surface of the first pad 210 may be bonded to a bottom surface of the second pad 710, and a top surface of the seventh dielectric pattern 314 may be bonded to a bottom surface of the eighth dielectric pattern 814.

Referring to FIG. 10A, a width W23 in the horizontal direction (e.g., the first direction D1) of a portion of the first pad 210 surrounded by the seventh dielectric pattern 314 may be substantially the same as a width W22 in the horizontal direction (e.g., the first direction D1) of a portion of the first pad 210 surrounded by the third dielectric pattern 313 and a width W21 in the horizontal direction (e.g., the first direction D1) of a portion of the first pad 210 surrounded by the first dielectric pattern 311.

Likewise, a width W26 in the horizontal direction (e.g., the first direction D1) of a portion of the second pad 710 surrounded by the eighth dielectric pattern 814 may be substantially the same as a width W25 in the horizontal direction (e.g., the first direction D1) of a portion of the second pad 710 surrounded by the sixth dielectric pattern 813 and a width W24 in the horizontal direction (e.g., the first direction D1) of a portion of the second pad 710 surrounded by the fourth dielectric pattern 811.

Referring to FIG. 10B, a width W23 in the horizontal direction (e.g., the first direction D1) of a portion of the first pad 210 surrounded by the seventh dielectric pattern 314 may be substantially the same as the width W22 in the horizontal direction (e.g., the first direction D1) of a portion of the first pad 210 surrounded by the third dielectric pattern 313. The width W22 in the horizontal direction (e.g., the first direction D1) of a portion of the first pad 210 surrounded by the third dielectric pattern 313 may be greater than a width W21 in the horizontal direction (e.g., the first direction D1) of a portion of the first pad 210 surrounded by the first dielectric pattern 311.

Likewise, a width W26 in the horizontal direction (e.g., the first direction D1) of a portion of the first pad 210 surrounded by the eighth dielectric pattern 814 may be substantially the same as a width W25 in the horizontal direction (e.g., the first direction D1) of a portion of the first pad 210 surrounded by the sixth dielectric pattern 813. Likewise, the width W25 in the horizontal direction (e.g., the first direction D1) of a portion of the first pad 210 surrounded by the sixth dielectric pattern 813 may be greater than a width W24 in the horizontal direction (e.g., the first direction D1) of a portion of the first pad 210 surrounded by the fourth dielectric pattern 811.

Referring to FIG. 10C, a width W22 in the horizontal direction (e.g., the first direction D1) of a portion of the first pad 210 surrounded by the third dielectric pattern 313 may be greater than a width W23 in the horizontal direction (e.g., the first direction D1) of a portion of the first pad 210 surrounded by the seventh dielectric pattern 314. The width W23 in the horizontal direction (e.g., the first direction D1) of a portion of the first pad 210 surrounded by the seventh dielectric pattern 314 may be greater than a width W21 in the horizontal direction (e.g., the first direction D1) of a portion of the first pad 210 surrounded by the first dielectric pattern 311. For example, a thermal conductivity of the third dielectric pattern 313 may be greater than that of the seventh dielectric pattern 314.

Likewise, a width W25 in the horizontal direction (e.g., the first direction D1) of a portion of the first pad 210 surrounded by the sixth dielectric pattern 813 may be greater than a width W26 in the horizontal direction (e.g., the first direction D1) of a portion of the first pad 210 surrounded by the eighth dielectric pattern 814. The width W26 in the horizontal direction (e.g., the first direction D1) of a portion of the first pad 210 surrounded by the eighth dielectric pattern 814 may be greater than a width W24 in the horizontal direction (e.g., the first direction D1) of a portion of the first pad 210 surrounded by the fourth dielectric pattern 811.

For example, a thermal conductivity of the sixth dielectric pattern 813 may be greater than that of the eighth dielectric pattern 814.

Referring to FIG. 10D, a width W23 in the horizontal direction (e.g., the first direction D1) of a portion of the first pad 210 surrounded by the seventh dielectric pattern 314 may be greater than a width W22 in the horizontal direction (e.g., the first direction D1) of a portion of the first pad 210 surrounded by the third dielectric pattern 313. The width W22 in the horizontal direction (e.g., the first direction D1) of a portion of the first pad 210 surrounded by the third dielectric pattern 313 may be greater than a width W21 in the horizontal direction (e.g., the first direction D1) of a portion of the first pad 210 surrounded by the first dielectric pattern 311. For example, a thermal conductivity of the third dielectric pattern 313 may be less than that of the seventh dielectric pattern 314.

Likewise, a width W26 in the horizontal direction (e.g., the first direction D1) of a portion of the first pad 210 surrounded by the eighth dielectric pattern 814 may be greater than a width W25 in the horizontal direction (e.g., the first direction D1) of a portion of the first pad 210 surrounded by the sixth dielectric pattern 813. The width W25 in the horizontal direction (e.g., the first direction D1) of a portion of the first pad 210 surrounded by the sixth dielectric pattern 813 may be greater than a width W24 in the horizontal direction (e.g., the first direction D1) of a portion of the first pad 210 surrounded by the fourth dielectric pattern 811.

For example, a thermal conductivity of the sixth dielectric pattern 813 may be less than that of the eighth dielectric pattern 814.

The semiconductor device 3 according to some embodiments of the present inventive concepts may include the first dielectric pattern 311 whose planarization efficiency is high to facilitate bonding between semiconductor dies when hybrid bonding is executed, and the third dielectric pattern 313 and the seventh dielectric pattern 314 whose thermal conductivities are high, and may show an arrangement of the dielectric patterns 311, 313, and 314. Thus, it may be possible to increase strength of the hybrid bonding and to easily disperse and discharge heat generated from pads and lines included in the semiconductor device 3. As a result, the semiconductor device 3 may improve in reliability.

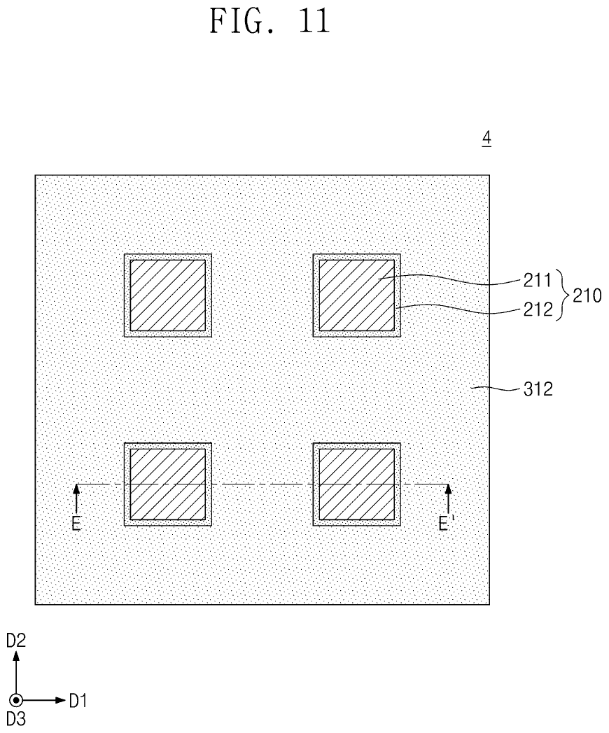

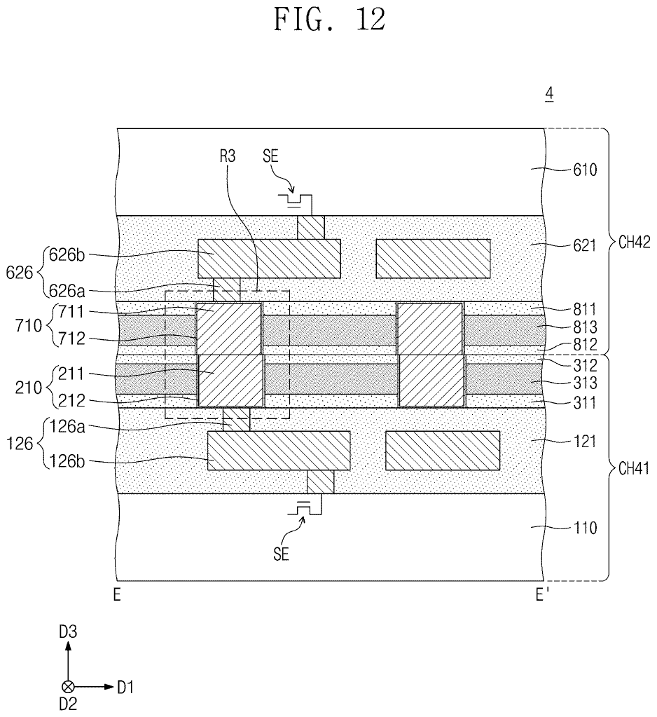

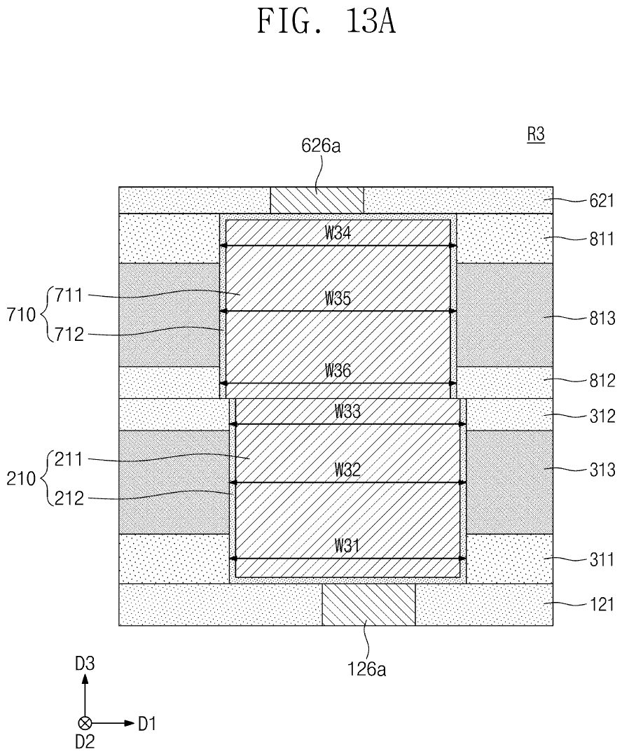

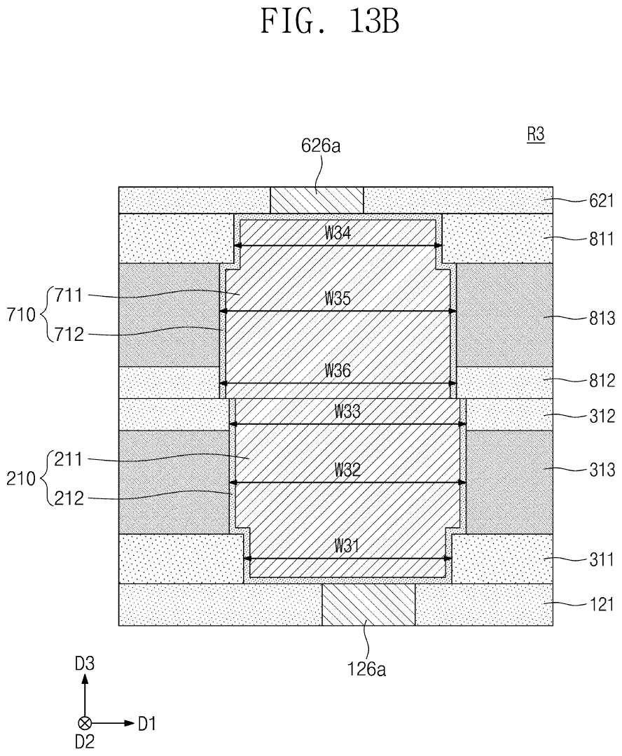

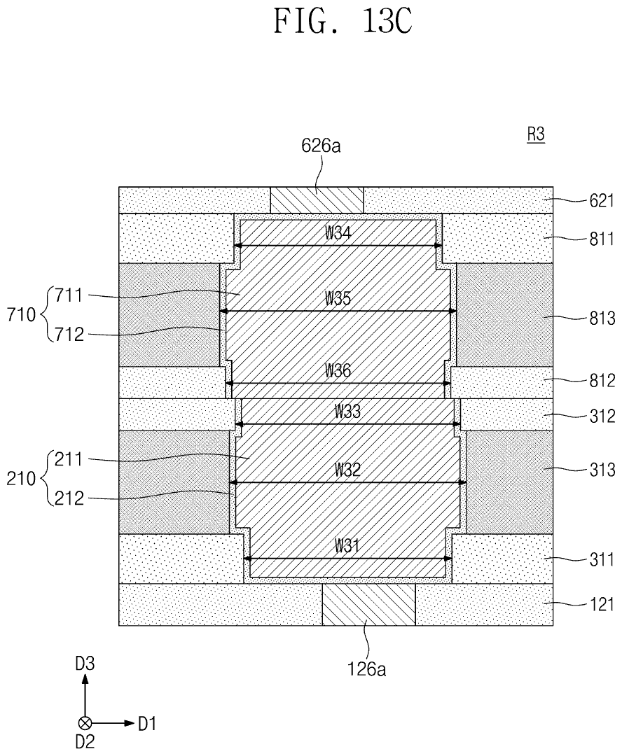

FIG. 11 illustrates a plan view showing a semiconductor device according to some example embodiments of the present inventive concepts. FIG. 12 illustrates a cross-sectional view taken along line C-C′ of FIG. 11. FIGS. 13A, 13B, and 13C illustrate enlarged views showing section R2 of FIG. 12. For brevity of description below, omission will be made to avoid an explanation repetitive to that of FIGS. 1 and 2.

Referring to FIGS. 11 and 12, a semiconductor device 4 according to some embodiments of the present inventive concepts may include a ninth semiconductor die CH41 and a tenth semiconductor die CH42 on the ninth semiconductor die CH41.

Referring to FIGS. 11 and 12 together with FIGS. 1 and 2, unlike the first semiconductor die CH11 of the semiconductor device 1, the ninth semiconductor die CH41 may have a modified arrangement of the second dielectric pattern 312 and the third dielectric pattern 313. Unlike the second semiconductor die CH12 of the semiconductor device 1, the tenth semiconductor die CH42 may have a modified arrangement of the fifth dielectric pattern 812 and the sixth dielectric pattern 813.

Referring back to FIGS. 11 and 12, the third dielectric pattern 313 may be provided on a top surface of the first dielectric pattern 311. The third dielectric pattern 313 may surround a lateral surface of the first pad 210, for example, a lateral surface of an intermediate portion of the first pad 210. For example, the third dielectric pattern 313 may contact the top surface of the first dielectric pattern 311 and the lateral surface of the intermediate portion of the first pad 210. The second dielectric pattern 312 may be provided on a top surface of the third dielectric pattern 313. The second dielectric pattern 312 may surround a lateral surface of the first pad 210, for example, a lateral surface of an upper portion of the first pad 210. For example, the second dielectric pattern 312 may contact the top surface of the third dielectric pattern 313 and the lateral surface of an upper portion of the first pad 210.

In addition, the sixth dielectric pattern 813 may be provided on a bottom surface of the fourth dielectric pattern 811. The sixth dielectric pattern 813 may surround a lateral surface of the first pad 210, for example, a lateral surface of an intermediate portion of the first pad 210. For example, the sixth dielectric pattern 813 may contact the bottom surface of the fourth dielectric pattern 811 and the lateral surface of the intermediate portion of the first pad 210. The fifth dielectric pattern 812 may be provided on a bottom surface of the sixth dielectric pattern 813. The fifth dielectric pattern 812 may surround a lateral surface of the first pad 210, for example, a lateral surface of an upper portion of the first pad 210. For example, the fifth dielectric pattern 812 may contact the bottom surface of the sixth dielectric pattern 813 and the lateral surface of an upper portion of the first pad 210.

Referring to FIG. 12, the semiconductor device 4 may have a hybrid bonding structure. A top surface of the ninth semiconductor die CH41 may be bonded to a bottom surface of the tenth semiconductor die CH42. For example, a top surface of the first pad 210 may be bonded to a bottom surface of the second pad 710, and a top surface of the second dielectric pattern 312 may be bonded to a bottom surface of the fifth dielectric pattern 812.

Referring to FIG. 13A, a width W33 in the horizontal direction (e.g., the first direction D1) of a portion of the first pad 210 surrounded by the second dielectric pattern 312 may be substantially the same as a width W32 in the horizontal direction (e.g., the first direction D1) of a portion of the first pad 210 surrounded by the third dielectric pattern 313 and a width W31 in the horizontal direction (e.g., the first direction D1) of a portion of the first pad 210 surrounded by the first dielectric pattern 311.

Likewise, a width W36 in the horizontal direction (e.g., the first direction D1) of a portion of the second pad 710 surrounded by the fifth dielectric pattern 812 may be substantially the same as a width W35 in the horizontal direction (e.g., the first direction D1) of a portion of the second pad 710 surrounded by the sixth dielectric pattern 813 and a width W34 in the horizontal direction (e.g., the first direction D1) of a portion of the second pad 710 surrounded by the fourth dielectric pattern 811.

Referring to FIG. 13B, a width W33 in the horizontal direction (e.g., the first direction D1) of a portion of the first pad 210 surrounded by the second dielectric pattern 312 may be substantially the same as a width W32 in the horizontal direction (e.g., the first direction D1) of a portion of the first pad 210 surrounded by the third dielectric pattern 313. The width W32 in the horizontal direction (e.g., the first direction D1) of a portion of the first pad 210 surrounded by the third dielectric pattern 313 may be greater than a width W31 in the horizontal direction (e.g., the first direction D1) of a portion of the first pad 210 surrounded by the first dielectric pattern 311.

Likewise, a width W36 in the horizontal direction (e.g., the first direction D1) of a portion of the second pad 710 surrounded by the fifth dielectric pattern 812 may be substantially the same as a width W35 in the horizontal direction (e.g., the first direction D1) of a portion of the second pad 710 surrounded by the sixth dielectric pattern 813. Likewise, the width W35 in the horizontal direction (e.g., the first direction D1) of a portion of the second pad 710 surrounded by the sixth dielectric pattern 813 may be greater than a width W34 in the horizontal direction (e.g., the first direction D1) of a portion of the second pad 710 surrounded by the fourth dielectric pattern 811.

Referring to FIG. 13C, a width W33 in the horizontal direction (e.g., the first direction D1) of a portion of the first pad 210 surrounded by the second dielectric pattern 312 may be smaller than a width W32 in the horizontal direction (e.g., the first direction D1) of a portion of the first pad 210 surrounded by the third dielectric pattern 313. The width W32 in the horizontal direction (e.g., the first direction D1) of a portion of the first pad 210 surrounded by the third dielectric pattern 313 may be greater than a width W31 in the horizontal direction (e.g., the first direction D1) of a portion of the first pad 210 surrounded by the first dielectric pattern 311. The width W33 in the horizontal direction (e.g., the first direction D1) of a portion of the first pad 210 surrounded by the second dielectric pattern 312 may be greater than the width W31 in the horizontal direction (e.g., the first direction D1) of a portion of the first pad 210 surrounded by the first dielectric pattern 311.

Likewise, a width W36 in the horizontal direction (e.g., the first direction D1) of a portion of the second pad 710 surrounded by the fifth dielectric pattern 812 may be smaller than a width W35 in the horizontal direction (e.g., the first direction D1) of a portion of the second pad 710 surrounded by the sixth dielectric pattern 813. Likewise, the width W35 in the horizontal direction (e.g., the first direction D1) of a portion of the second pad 710 surrounded by the sixth dielectric pattern 813 may be greater than a width W34 in the horizontal direction (e.g., the first direction D1) of a portion of the second pad 710 surrounded by the fourth dielectric pattern 811. The width W36 in the horizontal direction (e.g., the first direction D1) of a portion of the second pad 710 surrounded by the fifth dielectric pattern 812 may be greater than the width W34 in the horizontal direction (e.g., the first direction D1) of a portion of the second pad 710 surrounded by the fourth dielectric pattern 811.

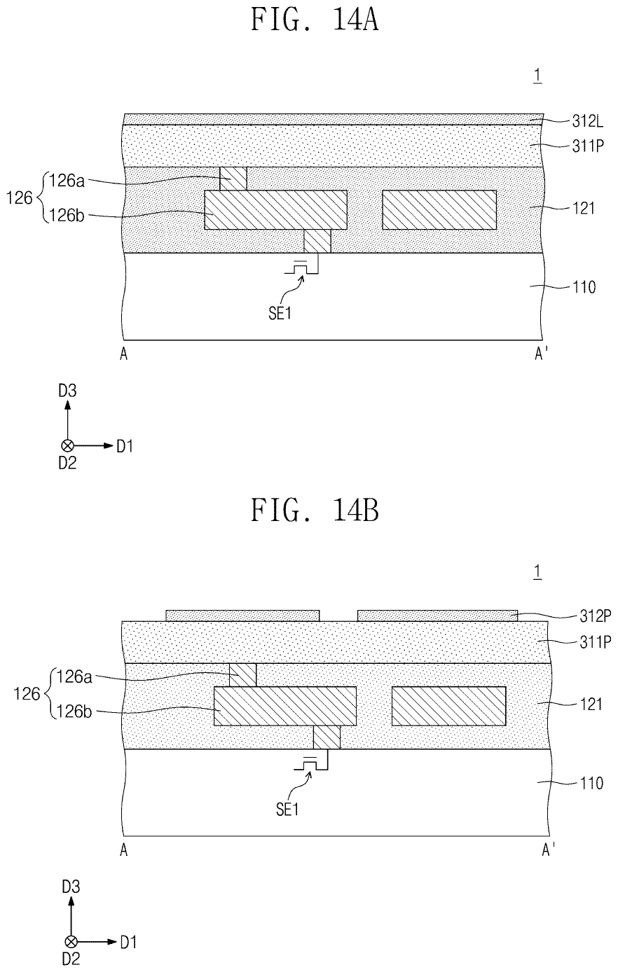

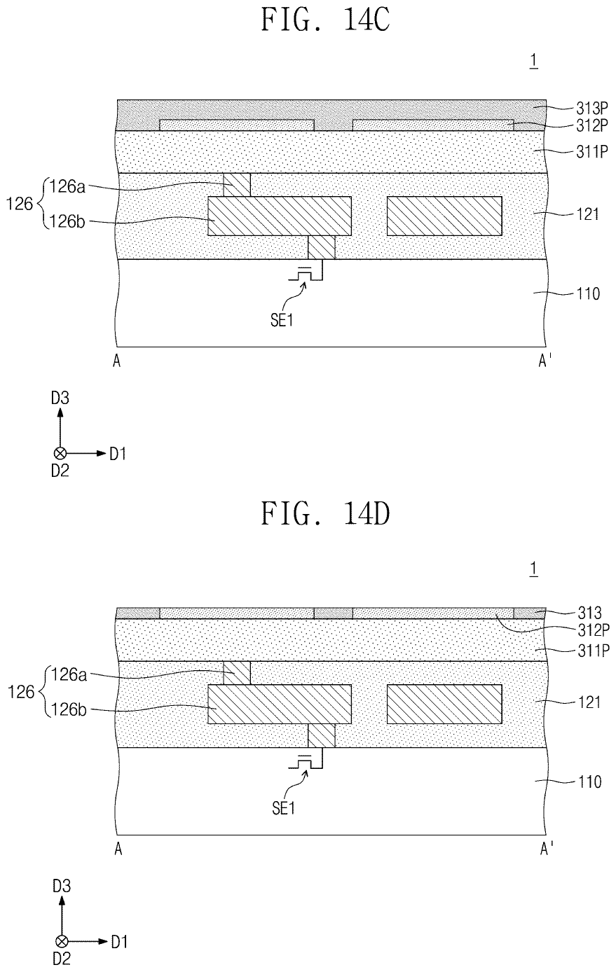

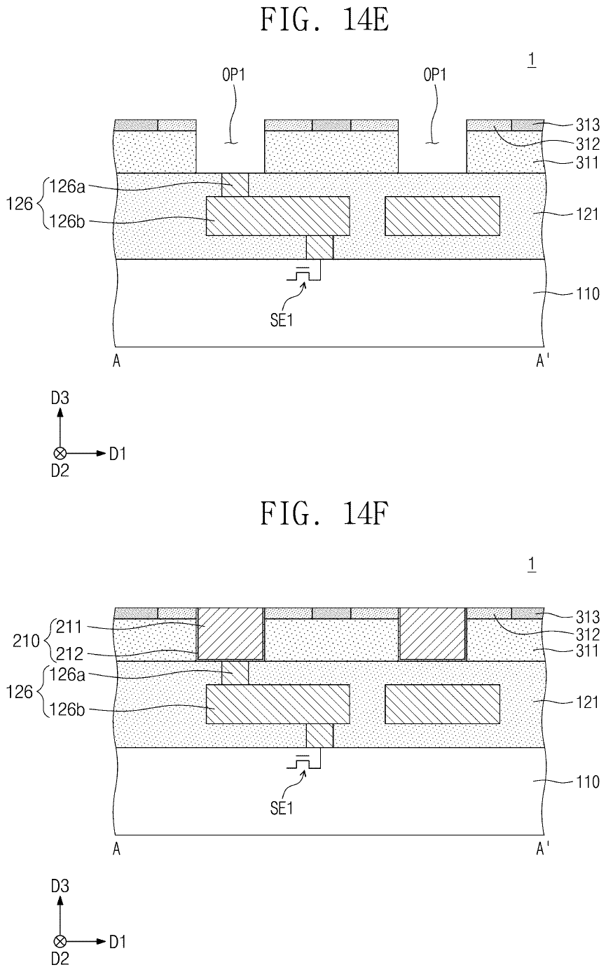

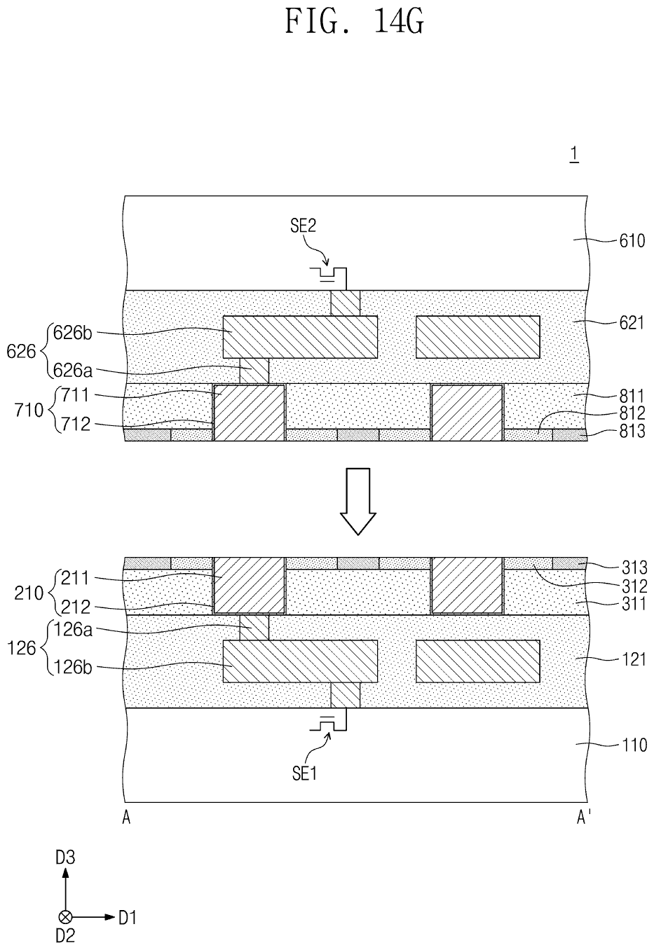

FIGS. 14 to 14G show a method of manufacturing a semiconductor device according to some example embodiments of the present inventive concepts. FIGS. 14A to 14G illustrate cross-sectional views that correspond to FIG. 2.

FIGS. 14A to 14F depict a first wafer process. A first wafer may include a first semiconductor substrate 110, a first wiring pattern 126, and a first dielectric layer 121 as discussed above with reference to FIG. 1.

Referring to FIG. 14A, the first wiring pattern 126 and the first dielectric layer 121 may be formed on the first semiconductor substrate 110. A third dielectric layer 311P may be formed on a top surface of the first dielectric layer 121 and the first wiring pattern 126. A fourth dielectric layer 312L may be formed on a top surface of the third dielectric layer 311P.

An ordinary process may be performed to form the first wiring pattern 126 and the first dielectric layer 121.

The formation of the third dielectric layer 311P may include forming a third preliminary dielectric layer (not shown) and planarizing the third preliminary dielectric layer. The formation of the third preliminary dielectric layer may include depositing a dielectric material on the top surface of the first dielectric layer 121. The third preliminary dielectric layer may include a material the same as that of the first dielectric pattern 311 of FIG. 1. The planarization of the third preliminary dielectric layer whose planarization efficiency is high may planarize a top surface of the first semiconductor die CH11 of FIG. 1, which may result in an increase in bonding strength.

The formation of the fourth dielectric layer 312L may include depositing a dielectric material on the top surface of the third dielectric layer 311P. The fourth dielectric layer 312L may include a material the same as that of the second dielectric pattern 312 of FIG. 1.

Referring to FIG. 14B, a portion of the fourth dielectric layer 312L may be removed to form a first dielectric preliminary pattern 312P. The partial removal of the fourth dielectric layer 312L may include etching a portion of the fourth dielectric layer 312L.

Referring to FIG. 14C, a fifth dielectric layer 313P may be formed on the third dielectric layer 311P and the first dielectric preliminary pattern 312P. The fifth dielectric layer 313P may cover the top surface of the third dielectric layer 311P, and may also cover a lateral surface and a top surface of the first dielectric preliminary pattern 312P. The formation of the fifth dielectric layer 313P may include depositing a dielectric material on the top surface of the third dielectric layer 311P and also on the lateral surface and the top surface of the first dielectric preliminary pattern 312P. The fifth dielectric layer 313P may include a material the same as that of the third dielectric pattern 313 of FIG. 1.

Referring to FIG. 14D, a portion of the fifth dielectric layer 313P may be removed to form a third dielectric pattern 313. The formation of the third dielectric pattern 313 may include planarizing a resultant structure of FIG. 14C. The planarization process may continue until the top surface of the first dielectric preliminary pattern 312P is exposed.

Referring to FIG. 14E, a portion of the first dielectric preliminary pattern 312P may be removed to form a second dielectric pattern 312. A portion of the third dielectric layer 311P may be removed to form a first dielectric pattern 311.

The formation of the second dielectric pattern 312 may include etching a portion of the first dielectric preliminary pattern 312P. The formation of the first dielectric pattern 311 may include etching a portion of the third dielectric layer 311P. The same mask pattern may be used to partially etch the first dielectric preliminary pattern 312P and the third dielectric layer 311P. The first dielectric preliminary pattern 312P and the third dielectric layer 311P may be partially etched to form a first opening OP1, and the first opening OP1 may be provided in plural.

Referring to FIG. 14F, a first pad 210 may be formed in the first opening OP1. The formation of the first pad 210 may include forming a first barrier pattern 212 and forming a first conductive pattern 211. The first barrier pattern 212 may cover a top surface of the first wiring pattern 126, the top surface of the first dielectric layer 121, a lateral surface of the first dielectric pattern 311, and a lateral surface of the second dielectric pattern 312. The first conductive pattern 211 may be formed on the first barrier pattern 212.

The formation of the first barrier pattern 212 may include depositing the barrier material of FIG. 1. The formation of the first conductive pattern 211 may include the conductive material of FIG. 1.

Referring to FIG. 14G, a second wafer may be provided. The second wafer may include a second semiconductor substrate 610, a second wiring pattern 626, and a second dielectric layer 621 as discussed above with reference to FIG. 1. The second wafer may be processed by the same procedure as described for processing the first wafer.

After the first wafer and the second wafer are processed, an activation may be performed on a top surface of the first pad 210, a top surface of the second dielectric pattern 312, a top surface of the third dielectric pattern 313, a bottom surface of the second pad 710, a bottom surface of the fifth dielectric pattern 812, and a bottom surface of the sixth dielectric pattern 813. The activation may include, for example, performing a plasma treatment on a top surface of the first wafer and a bottom surface of the second wafer. The plasma treatment may include allowing a plasma material to contact the top surface of the first wafer and the bottom surface of the second wafer. For example, the plasma material may include an O2 plasma material.

Afterwards, the first wafer and the second wafer may be bonded to each other. For example, the top surface of the second dielectric pattern 312 may be bonded to the bottom surface of the fifth dielectric pattern 812, and the top surface of the third dielectric pattern 313 may be bonded to the bottom surface of the sixth dielectric pattern 813.

Then, an annealing process may be performed on a resultant structure in which the first wafer and the second wafer are bonded to each other. In the annealing process, materials included in the first pad 210 and the second pad 710 may diffuse to achieve a contact between the first pad 210 and the second pad 710.

After or before the bonding of the first wafer and the second wafer, an additional process may be performed to form a through via that penetrates the first semiconductor substrate 110 or the second semiconductor substrate 610 for connection with an external substrate or an external electronic device.

The first wafer and the second wafer may undergo a sawing process to fabricate a semiconductor device including a first semiconductor die CH11 and a second semiconductor die CH12 as discussed in FIG. 1.

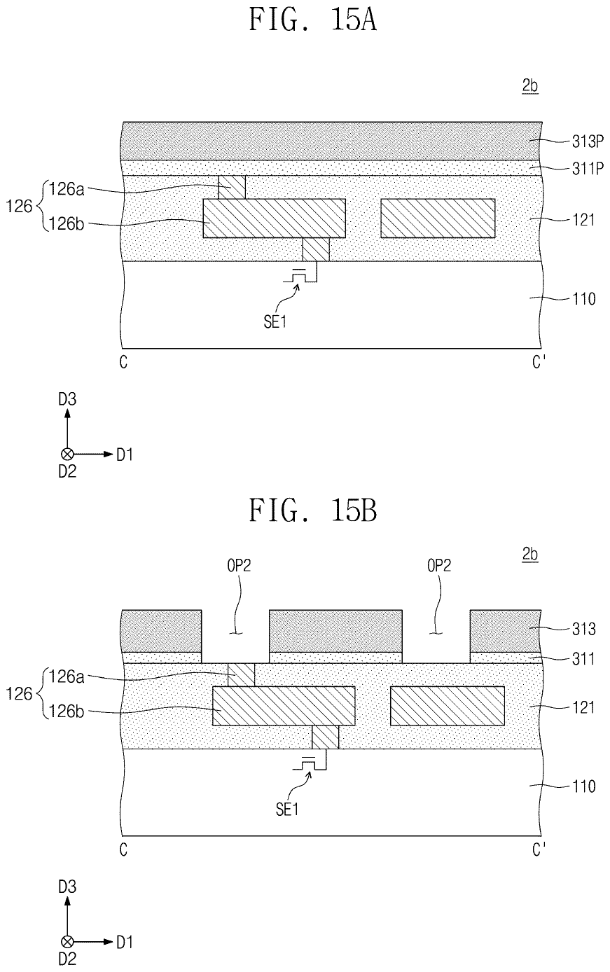

FIGS. 15A and 15B show a method of manufacturing a semiconductor device according to some example embodiments of the present inventive concepts. FIGS. 15A and 15B illustrate cross-sectional views that correspond to FIG. 6. For brevity of description, omission will be made to avoid an explanation repetitive to that of FIGS. 14A to 14G.

Referring to FIG. 15A, a third dielectric layer 311P and a fifth dielectric layer 313P may be formed. The fifth dielectric layer 313P may be formed on the third dielectric layer 311P.

Referring to FIG. 15B, a portion of the third dielectric layer 311P may be removed to form a first dielectric pattern 311. A portion of the fifth dielectric layer 313P may be removed to form a third dielectric pattern 313.

The formation of the third dielectric pattern 313 may include etching a portion of the fifth dielectric layer 313P. The formation of the first dielectric pattern 311 may include etching a portion of the third dielectric layer 311P. The same mask pattern may be employed to partially etch the fifth dielectric layer 313P and the third dielectric layer 311P. The fifth dielectric layer 313P and the third dielectric layer 311P may be partially etched to form a second opening OP2, and the second opening OP2 may be provided in plural.

Referring to FIG. 15B together with FIG. 7B, the second opening OP2 may have a shape substantially the same as that of the first pad 210, and a width W12 of the second opening OP2 surrounded by the third dielectric pattern 313 may be greater than a width W11 of the second opening OP2 surrounded by the first dielectric pattern 311. Even when the same mask pattern is used to perform an etching process, a larger amount of dielectric material may be horizontally etched because a thermal conductivity of the third dielectric pattern 313 is greater than that of the first dielectric pattern 311.

A semiconductor device according to the present inventive concepts may include a dielectric pattern whose planarization efficiency is high, a dielectric pattern whose bonding strength is high, and/or a dielectric pattern whose thermal conductivity is high, and may provide an arrangement of the dielectric patterns. Thus, it may be possible to increase strength of hybrid bonding and to easily disperse and discharge heat generated from pads and lines included in the semiconductor device. As a result, the semiconductor device may improve in reliability.

Although the present invention have been described in connection with the some embodiments of the present inventive concepts illustrated in the accompanying drawings, it will be understood by one of ordinary skill in the art that variations in form and detail may be made therein without departing from the spirit and essential feature of the present inventive concepts. The above disclosed embodiments should thus be considered illustrative and not restrictive.

What is claimed is:

1. A semiconductor device, comprising:
a first semiconductor die; and
a second semiconductor die on the first semiconductor die,
wherein the first semiconductor die comprises:
a first pad;
a first dielectric pattern that surrounds a lateral surface of the first pad; and
a second dielectric pattern that surrounds a lateral surface of the first dielectric pattern,
wherein the second semiconductor die comprises a second pad in contact with the first pad,
wherein the first dielectric pattern comprises a first dielectric material,
wherein the second dielectric pattern comprises a second dielectric material different from the first dielectric material, and
wherein a thermal conductivity of the second dielectric material is greater than a thermal conductivity of the first dielectric material.

2. The semiconductor device of claim 1, wherein the second dielectric material comprises at least one selected from aluminum oxide (AlO), aluminum nitride (AlN), boron nitride (BN), diamond, and any mixture thereof.

3. The semiconductor device of claim 1, wherein the thermal conductivity of the second dielectric material is greater than about 10 W/m·K.

4. The semiconductor device of claim 1, wherein the thermal conductivity of the second dielectric material is in a range of about 30 W/m·K to about 3,000 W/m·K.

5. The semiconductor device of claim 1, wherein the thermal conductivity of the first dielectric material is equal to or less than about 10 W/m·K.

6. The semiconductor device of claim 1, wherein the first dielectric material comprises at least one selected from silicon oxide, silicon nitride, silicon oxynitride, and any mixture thereof.

7. The semiconductor device of claim 1, wherein each of the first dielectric pattern and the second dielectric pattern is in contact with the second semiconductor die.

8. The semiconductor device of claim 1, further comprising:
a third dielectric pattern that surrounds the lateral surface of the first pad,
wherein the third dielectric pattern is at a level lower than a level of the second dielectric pattern,
wherein the third dielectric pattern comprises a third dielectric material different from the second dielectric material, and
wherein a thermal conductivity of the third dielectric material is less than the thermal conductivity of the second dielectric material.

9. The semiconductor device of claim 8, wherein the third dielectric material comprises at least one selected from silicon oxide, silicon nitride, silicon oxynitride, and any mixture thereof.

10. A semiconductor device, comprising:
a first semiconductor die; and
a second semiconductor die on the first semiconductor die,
wherein the first semiconductor die comprises:
a first pad;
a first dielectric pattern that surrounds a lateral surface of the first pad; and
a second dielectric pattern on a top surface of the first dielectric pattern and surrounding the lateral surface of the first pad,
wherein the second semiconductor die comprises a second pad in contact with the first pad,
wherein the first dielectric pattern comprises a first dielectric material,
wherein the second dielectric pattern comprises a second dielectric material different from the first dielectric material,
wherein the first dielectric material comprises at least one selected from silicon oxide, silicon nitride, silicon oxynitride, and any mixture thereof, and
wherein a thermal conductivity of the second dielectric material is greater than a thermal conductivity of the first dielectric material.

11. The semiconductor device of claim 10,
wherein the second semiconductor die further comprises a third dielectric pattern that surrounds a lateral surface of the second pad,
wherein the second dielectric pattern is in contact with the third dielectric pattern.

12. The semiconductor device of claim 10, wherein a width of a portion of the first pad surrounded by the first dielectric pattern is less than a width of a portion of the first pad surrounded by the second dielectric pattern.

13. The semiconductor device of claim 10, further comprising:
a third dielectric pattern that surrounds the lateral surface of the first pad,
wherein the second dielectric pattern surrounds a lateral surface of the third dielectric pattern,
wherein the third dielectric pattern comprises a third dielectric material different from the first dielectric material and the second dielectric material, and
wherein a thermal conductivity of the third dielectric material is less than the thermal conductivity of the second dielectric material.

14. The semiconductor device of claim 13, wherein the third dielectric material comprises at least one selected from silicon oxide, silicon nitride, silicon oxynitride, and any mixture thereof.

15. The semiconductor device of claim 10, further comprising:
a third dielectric pattern that surrounds the lateral surface of the first pad,
wherein the third dielectric pattern comprises a third dielectric material different from the first dielectric material and the second dielectric material, and
wherein the second dielectric pattern is between the first dielectric pattern and the third dielectric pattern.

16. The semiconductor device of claim 15,
wherein the thermal conductivity of the second dielectric material is greater than about 10 W/m·K, and
wherein a thermal conductivity of the third dielectric material is greater than the thermal conductivity of the second dielectric material.

17. The semiconductor device of claim 15,
wherein a thermal conductivity of the third dielectric material is greater than about 10 W/m·K, and
wherein the thermal conductivity of the second dielectric material is greater than the thermal conductivity of the third dielectric material.

18. The semiconductor device of claim 15,
wherein the thermal conductivity of the second dielectric material is greater than about 10 W/m·K, and
wherein each of the thermal conductivity of the first dielectric material and a thermal conductivity of the third dielectric material is equal to or less than about 10 W/m·K.

19. The semiconductor device of claim 15, wherein a width of a portion of the first pad surrounded by the second dielectric pattern is different from a width of a portion of the first pad surrounded by the third dielectric pattern.

20. A semiconductor device, comprising:
a first semiconductor die; and
a second semiconductor die on the first semiconductor die,
wherein the first semiconductor die comprises:
a wiring pattern;
a dielectric layer that surrounds a lateral surface of the wiring pattern;
a first pad on the wiring pattern; and
a dielectric pattern that surrounds a lateral surface of the first pad,
wherein the second semiconductor die comprises a second pad in contact with the first pad,
wherein the dielectric layer comprises a first dielectric material,
wherein the dielectric pattern comprises a second dielectric material different from the first dielectric material,
wherein the first dielectric material comprises at least one selected from silicon oxide, silicon nitride, silicon oxynitride, and any mixture thereof, and
wherein a thermal conductivity of the second dielectric material is greater than a thermal conductivity of the first dielectric material.
